(19) United States
(12) Patent Application Publication
(10) Pub. No.: US 2011/0020957 A1
(43) Pub. Date: Jan. 27, 2011

(54) POSITIONING OF SEMICONDUCTOR SUBSTRATES IN A FURNACE

(76) Inventors: Cedric Angellier, Le Cheylas (FR); William Palmer, Brignoud (FR)

Correspondence Address: WINSTON & STRAWN LLP;PATENT DEPARTMENT, 1700 K STREET, N.W., WASHINGTON, DC, 20006, US

(21) Appl. No.: 12/830,988

(22) Filed: Jul. 6, 2010

(30) Foreign Application Priority Data
Jul. 27, 2009 (FR) FR 0 955 236

(51) Int. Cl. H01L 21/66; B05C 13/02; G06F 15/00

(52) U.S. Cl. 438/7; 432/32; 702/150; 257/E21.53

(57) ABSTRACT

Methods of positioning semiconductor substrates in a furnace. One method determines a centered position of the substrates by conducting a heat treating to form an oxide layer on the substrate and measuring the substrate thickness at several points along its oxidized surface to determine a centered position. Also, a method of calibrating a device for heat treatment of the substrates, with the device including a positioner for providing the substrates on a retention support in the furnace. The positioner includes a memory unit that stores positioning parameters, and an actuator for positioning the substrate on the support according to the positioning parameters. The method includes positioning a test substrate on the support in a starting position according to starting parameters, determining a centered position for the test substrate, determining centering parameters corresponding to the centered position of the test substrate and storing the centering parameters in the memory unit.

### BACKGROUND

The present invention relates to the positioning of semiconductor substrates in a furnace for heat treatment. More precisely, it relates to the positioning of semiconductor substrates on a retention support in a furnace with a view to carrying out a heat treatment.

It may be necessary to apply a heat treatment to a semiconductor substrate, for example to increase its strength or to reduce structural defects induced by a production process.

Referring to FIGS. 1a and 1b, a circular semiconductor substrate 10 is conventionally placed, in certain furnaces, horizontally on an annular retention support 20 shown in a bottom view in FIG. 1a and in a sectional side view in FIG. 1b.

During a heat treatment, heat from the substrate 1 is dissipated in the annular support 20 via the contact zone C, shown cross-hatched in FIG. 1a. If the substrate is off-center relative to the annular support, this heat dissipation is asymmetrical, the resulting thermal gradients causing structural defects in the substrate, for example defects of the slip line type. It is therefore preferable for the substrate to be centered as closely as possible on the annular support before the heat treatment is started.

There are methods for qualitatively determining whether the substrate is centered relative to the support. For example, the substrate may be rotated on a support rotating relative to its center and the centering may be optically evaluated from the shape described by the rotating substrate. This method is used to determine whether the substrate is incorrectly placed, but provides no quantitative indication about the shift required to position the substrate at the center of the support. The substrate must therefore be moved by trial and error in order to obtain the desired centered position. This method is therefore costly in terms of time and is not very precise.

There is a method for quantitatively evaluating the offset of the substrate relative to the support, however, and this method includes a step of implanting species (for example, boron or phosphorus) capable of migrating at high temperature at a defined position on the surface of the substrate. Next, a heat treatment is applied to the substrate and then the migration of the species is evaluated by an electrical resistance measurement. The migration of the species provides quantitative information about the temperature symmetry during the heat treatment, the information being indicative of the centering of the substrate on the support. It is then possible to center the substrate on the basis of this quantitative information. One drawback of this method is that the implantation of species into the substrate is an expensive step to implement and requires further specific equipment.

Accordingly, there remains a need for improvements in the area of centering semiconductor substrates in heat treatment furnaces in order to facilitate and improve the heat treatment of such substrates.

### SUMMARY OF THE INVENTION

The present invention now alleviates the drawbacks of the prior art and provides a simple method for centering a substrate on an annular support preferably for use in a furnace for heat treatment of such substrates.

In one aspect, the invention relates to a method of determining a centered position of a semiconductor substrate placed in an annealing furnace in a starting position on a retention support. This method comprises heat treating the substrate in its starting position for a sufficient time and at a sufficient temperature in the presence of a furnace gas to form a layer on the substrate; measuring thickness of the substrate at several points, with the position of the measurement points on the substrate being known; and determining, on the basis of the measured thicknesses and the starting position, a centered position for the substrate on the support.

The substrate may be heat treated to form an oxide layer, a nitride layer or another layer on the upper surface of the substrate. Also, the method preferably further comprises measuring the thickness of the substrate at points concentrically arranged along the upper surface of the substrate.

Another aspect of the invention is a method for calibrating a device for the heat treatment of semiconductor substrates. The device includes means for positioning semiconductor substrates on a retention support in a furnace, wherein the positioning means comprises a memory unit for storing positioning parameters, and an actuator for positioning a substrate on the support according to positioning parameters stored in the memory unit. This method comprises positioning by the actuator a test substrate on the support in a starting position according to predetermined starting parameters; determining a centered position for the test substrate according to the other methods disclosed herein; determining centering parameters corresponding to the centered position of the test substrate; and storing the centering parameters in the memory unit of the positioning means.

This method preferably comprises repeating the method steps according to a given number of iterations, with the centering parameters determined at each iteration being taken as starting parameters for the next iteration.

A third aspect of the invention relates to a device for the heat treatment of semiconductor substrates. This device comprises a furnace with a retention support for receiving such substrates; a measurement unit for determining substrate thickness at several measurement points; and positioning means. The positioning means generally comprises a memory unit for storing positioning parameters corresponding to the positions of the substrate on the support, an actuator for positioning the substrate on the support according to positioning parameters stored in the memory unit; and a processing unit for determining, as a function of a starting position and measurements by the measurement unit, a centered position and centering parameters based on the centered position. Thus, the memory unit can store the centering parameters so that the actuator is able to position semiconductor substrates on the support in the centered position. Advantageously, the processing means includes the memory unit and is operatively associated with the actuator for centering the substrates on the retention support.

### BRIEF DESCRIPTION OF THE FIGURES

Other features and advantages of the invention will emerge from the following description, which is purely illustrative and non-limiting and must be read in conjunction with the appended drawings in which:

FIGS. 1a and 1b, already commented upon, show schematically the prior art positioning of a substrate on an annular support in a bottom view and in a sectional side view, respectively;

FIGS. 2a and 2b show schematically a substrate on an annular support after heat treatment according to one possible way of implementing the methods according to the first and second aspects of the invention, in a bottom view and in a sectional side view, respectively;

FIG. 2c shows, schematically in a top view, measurement points on the oxide layer covering a substrate according to one possible way of implementing the first and second aspects of the invention;

FIG. 3 shows, in the form of a block diagram, a method of determining a centered position of a semiconductor substrate according to one possible way of implementing the first aspect of the invention;

FIG. 4 shows, in the form of a block diagram, a method of calibrating a device for the heat treatment of semiconductor substrates, in accordance with one possible way of implementing the second aspect of the invention; and

FIG. 5 shows, in the form of a block diagram, a device for the heat treatment of semiconductor substrates according to one possible embodiment of the third aspect of the invention.

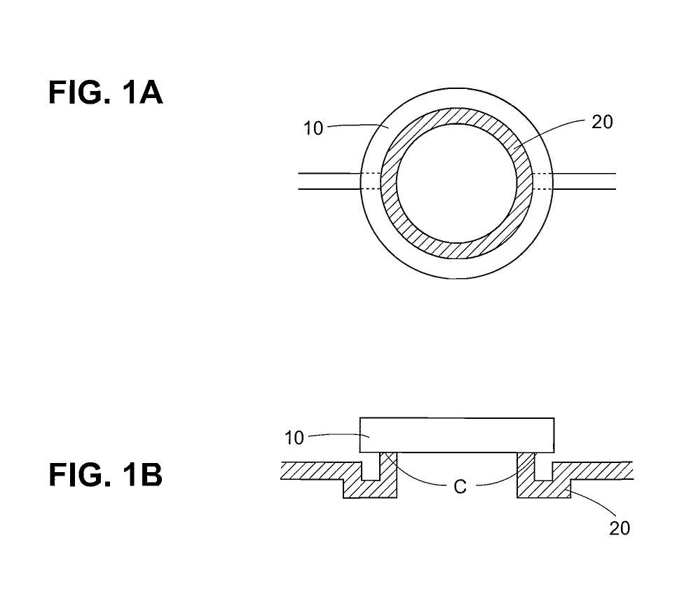

### DETAILED DESCRIPTION OF THE INVENTION

For this purpose, the invention provides, according to a first aspect, a method of determining a centered position of a semiconductor substrate placed in an annealing furnace, in a starting position, on a retention support in the furnace, wherein the method comprises:
heat treatment of the substrate in its starting position, the treatment resulting in the formation of an oxide layer on the substrate;
measurement of the thickness of the substrate at several points on the oxidized surface of the substrate, the position of the measurement points on the substrate being known; and
determination, on the basis of the measurement step and the starting position, of a centered position of the substrate on the support.

The invention also provides, according to a second aspect, a method of calibrating a device for the heat treatment of semiconductor substrates, the device comprising means for positioning semiconductor substrates on a retention support in a furnace. The positioning means is generally a positioner which comprises a memory unit, intended to store positioning parameters, and an actuator capable of positioning a substrate on the support according to positioning parameters stored in the memory unit. The method generally comprises:
positioning by the actuator of a test substrate on the support in a starting position according to predetermined starting parameters;
application of the steps of the method of determining a centered position according to the first aspect of the invention to the test substrate;
determination of centering parameters corresponding to the centered position of the test substrate; and
storage of the centering parameters in the memory unit.

The calibrating method according to the second aspect of the invention is advantageously iterative, all the steps of the method being repeated according to a given number of iterations, with the centering parameters determined at each iteration being taken as starting parameters for the next iteration.

According to a third aspect, the invention provides a device for the heat treatment of semiconductor substrates, comprising:
a furnace with a retention support;
a measurement unit for determining a thickness of the substrate at several measurement points; and
positioning means comprising:
   a memory unit for storing positioning parameters corresponding to positions of a substrate on the support,
   an actuator for positioning a substrate on the support according to positioning parameters stored in the memory unit, and
   a processing unit for determining, as a function of a starting position and measurements by the measurement unit, a centered position and for determining centering parameters from the centered position,

The memory unit is furthermore designed to store centering parameters so that the actuator is able to position semiconductor substrates on the support in the centered position.

The invention has many advantages. The invention provides a simple way of determining a centered position of a substrate on an annular support on the basis of a starting position and a heat treatment. The invention also makes it possible to calibrate a device for the heat treatment of substrates, so as to reduce the defects induced by an offset of the substrates to be treated on the annular support. As a result substrates that are heat treated after being centered or calibrated according to the methods disclosed herein are of better quality in that they have reduced defects.

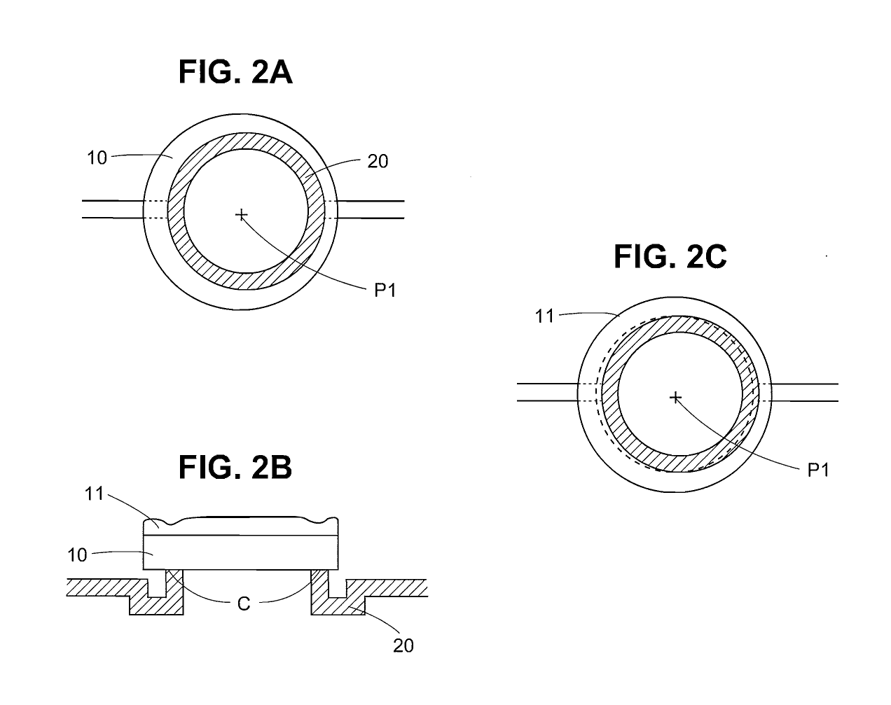

Referring to FIGS. 2a and 2b, the purpose of the method according to the first aspect of the invention is to determine a centered position of a semiconductor substrate 10 placed on a retention support 20 in an annealing furnace.

Initially, the substrate is placed on the support 20, assumed to be annular, in a starting position P1 a priori off-center relative to the center of the support 20. In FIG. 2a, the substrate 10 has a disc shape and its position P1 is identified by its center. However, the invention is not limited to a disc-shaped substrate, and extends more generally to any polygonal or other plane substrate shape.

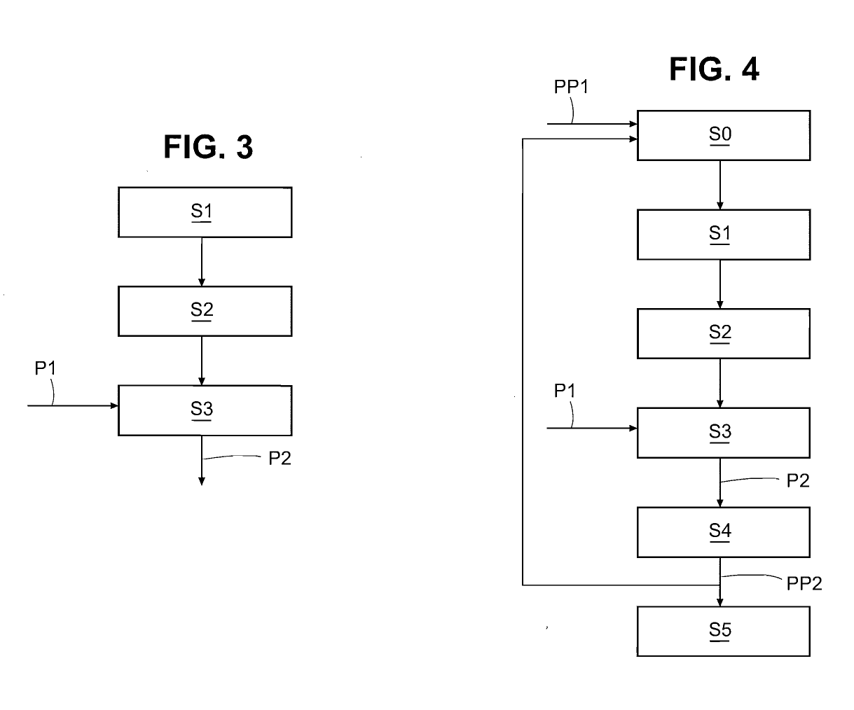

Referring to FIG. 3, the method according to the first aspect of the invention comprises a first step S1 for heat treatment of the substrate 10 in its starting position P1. This treatment S1 results in the formation of an oxide layer 11 on the substrate 10.

In the context of the invention, the term “oxide layer” is understood to mean any layer that can be grown during a heat treatment on the semiconductor substrate, the thickness of the layer depending on the temperature. This definition is not exclusively limited to oxides, and includes other grown layers that can be achieved in the furnace based on the material of the semiconductor substrate and of the gases that are present in the furnace. Another particular layer of interest is one based on nitrides.

A distinction is made below between a lower surface of the substrate 10, in contact with the support 20, and an upper surface on the opposite side from the lower surface. Preferably, the oxide layer 11 is located on the upper surface of the substrate 10.

As shown in FIG. 2b, the oxide layer 11 has a thickness that varies, most particularly at the point corresponding to the contact zone C between the substrate 10 and the support 20. The heat dissipation in the support 20 slows down the growth of the oxide layer 11. The variations in thickness of the layer 11 thus constitute an impression of the support 20 in contact with the lower surface of the substrate 10. This impression is shown cross-hatched in FIG. 2c (in a top view).

The method according to the first aspect of the invention further includes a step S2 of measuring the thickness of the substrate at several points on the oxidized surface of the substrate, i.e., in layer 11. The position of each measurement point relative to the support 20 is known and predetermined. For example, a dotted circle concentric with the support 20 is shown, constituting one possible distribution of the points for measuring the thickness of the layer according to the first aspect of the invention.

It may be seen in FIG. 2c that this circle is partly located in the cross-hatched zone in which the thickness of the oxide layer 11 is smaller. Thus, the measured thickness will be smaller in this zone, indicating that the substrate is off-center relative to the support. Of course, the cross-hatching merely shows a schematic illustration of the impression of the annular support on the oxide layer 11. In fact, this impression is not very pronounced, but represents more of a degradation in thickness uniformity as may be readily imagined from FIG. 2b. The thickness measurement may be carried out by ellipsometry or by any other suitable means known to those skilled in the art.

The dotted circle in FIG. 2c is given by way of non-limiting example. Other configurations of measurement point positions are envisaged in the context of the invention. In particular, the invention covers the measurement point positions already explained by the Applicant in patent application WO 2006/051243.

The method according to the first aspect of the invention also includes a step S3, on the basis of the measurement step S2 and the starting position P1, of determining a centered position P2 of the substrate 10 on the support 20. Advantageously, the determination of the position P2 comprises predetermining a direction and sense of the offset from P1 and calculating the amount of offset in the predetermined direction and sense.

To give a non-limiting example, the direction and sense of the offset from P1 may be determined by the vector connecting the point where the measured thickness is the greatest to the point where it is the smallest. Advantageously, the amount of offset is determined as a function of the thickness measured at several measurement points, preferably all of the measurement points, for example by comparing the results of the measurement with a predetermined model.

The method according to the first aspect of the invention thus makes it possible to quantitatively determine the shift to be made with respect to the starting position P1 in order to obtain a centered position P2 relative to the support 20. Moreover, the steps of this method may be implemented for calibrating a device used for the heat treatment of semiconductor substrates.

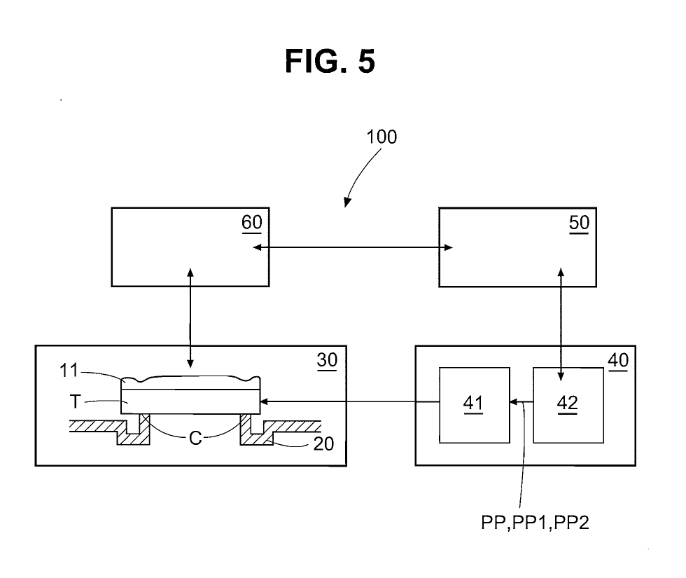

For this purpose, the invention provides, according to a second aspect, a calibrating method as shown in FIG. 4. The device intended to be calibrated is a device according to the third aspect of the invention, shown in the form of a block diagram in FIG. 5. This device, with the reference 100, comprises means 40 for positioning semiconductor substrates 10 on a retention support 20 in a furnace 30. The positioning means comprises a memory 42 designed to store positioning parameters PP, and an actuator 41 capable of positioning a substrate 10 on the support 20 according to positioning parameters PP stored in the memory unit 42.

The method according to the second aspect of the invention includes a step S0 of positioning a test substrate T on the support 20 in a starting position P1 according to predetermined starting parameters PP1. This step is carried out by the actuator 41 of the device according to the third aspect of the invention. The parameters PP1 are prestored in the memory unit 42. These may be default parameters, parameters set by a user, or, as will be seen later in the advantageous case of an iterative method, parameters determined during a preceding iteration.

The method according to the second aspect of the invention further includes determining a centered position P2 by applying the steps of the method according to the first aspect of the invention to the test substrate T, and also a step S4 of determining centering parameters PP2 corresponding to the centered position P2. The measurements are carried out by a measurement unit 60 of the device according to the third aspect of the invention. The unit 60 transmits the measurements to a processing unit 50 of the device, configured to determine, as a function of the starting position P1 of the test substrate T and the transmitted measurements, the centered position P2 and deduce therefrom the centering parameters PP2. The processing unit is part of the positioning means and conveniently can include the memory unit for storing these parameters.

The method according to the second aspect of the invention further includes a step of storing these parameters PP2 in the memory unit 42. The test substrate T is then taken off the support 20 and removed from the annealing furnace 30. The substrates to be treated will then be positioned in the position P2 in the furnace, which is thus calibrated for a heat treatment in which the temperature asymmetries due to an off-center position of the substrates on the support 20 are reduced. The position P2 thus obtained according to the invention is centered to one tenth of a millimeter. For greater precision in this position, the method according to the second aspect of the invention may be applied a second time with a new test substrate, taking as starting position the determined centering position.

In general, the method according to the second aspect of the invention is advantageously iterative, the starting parameters for one iteration being the centering parameters determined in the preceding iteration. A new test substrate is used at each iteration. Two iterations of the method according to the second aspect of the invention are sufficient for obtaining a precision of the order of one hundredth of a millimeter.

What is claimed is:

1. A method of determining a centered position of a semiconductor substrate placed in an annealing furnace in a starting position on a retention support, which comprises:
heat treating the substrate in its starting position for a sufficient time and at a sufficient temperature in the presence of a furnace gas to form a layer on the substrate;
measuring thickness of the substrate at several points, with the position of the measurement points on the substrate being known; and
determining, on the basis of the measured thicknesses and the starting position, a centered position for the substrate on the support.

2. The method of claim 1 wherein the substrate is heat treated to form an oxide layer on the upper surface of the substrate.

3. The method of claim 1 wherein the substrate is heat treated to form a nitride layer on the upper surface of the substrate.

4. The method of claim 1 which further comprises measuring the thickness of the substrate at points concentrically arranged along the upper surface of the substrate.

5. A method for calibrating a device for the heat treatment of semiconductor substrates, with the device comprising means for positioning semiconductor substrates on a retention support in a furnace, wherein the positioning means comprises a memory unit for storing positioning parameters, and an actuator for positioning a substrate on the support according to positioning parameters stored in the memory unit, wherein the method comprises:
positioning by the actuator a test substrate on the support in a starting position according to predetermined starting parameters;
determining a centered position for the test substrate according to the method of claim 1;
determining centering parameters corresponding to the centered position of the test substrate; and
storing the centering parameters in the memory unit of the positioning means.

6. The method of claim 5 which further comprises repeating the method according to a given number of iterations, with the centering parameters determined at each iteration being taken as starting parameters for the next iteration.

7. A device for the heat treatment of semiconductor substrates, comprising:
a furnace with a retention support for receiving such substrates;
a measurement unit for determining substrate thickness at several measurement points; and
positioning means comprising:
a memory unit for storing positioning parameters corresponding to the positions of the substrate on the support,
an actuator for positioning the substrate on the support according to positioning parameters stored in the memory unit; and
a processing unit for determining, as a function of a starting position and measurements by the measurement unit, a centered position and centering parameters based on the centered position;
such that the memory unit stores centering parameters so that the actuator is able to position semiconductor substrates on the support in the centered position.

8. The device of claim 7, wherein the processing means includes the memory unit and is operatively associated with the actuator for centering the substrates on the retention support.
